(19) United States
(12) Patent Application Publication
(10) Pub. No.: US 2026/0134896 A1
(43) Pub. Date: May 14, 2026

(54) FAST MOSFET DEVICE THRESHOLD VOLTAGE SENSING SCHEME FOR SEMICONDUCTOR NON-VOLATILE MEMORY

(71) Applicant: FS-SEMI Semiconductor Corporation., Ltd., Hsinchu County (TW)

(72) Inventors: Lee Wang, Diamond Bar, CA (US); Xiang Su, ZheJiang (CN); Yong Tao, ZheJiang (CN); YiLin Wang, ZheJiang (CN)

(21) Appl. No.: 18/986,769

(22) Filed: Dec. 19, 2024

(30) Foreign Application Priority Data
Nov. 8, 2024 (CN) 202411602816.1

(51) Int. Cl. G11C 7/06; G11C 16/26

(52) U.S. Cl. CPC G11C 7/062; G11C 16/26

(57) ABSTRACT

A non-differential sensing circuit for semiconductor Non-Volatile Memories (NVMs) is disclosed. The circuit comprises a half latch, a switch device, a reset device, a PMOSFET device and an NMOSFET device. The half latch has a voltage signal input node and a digital voltage signal output node. The PMOSFET device has a source connected to a digital voltage rail and a drain connected to the voltage signal input node. The NMOSFET device has a drain connected to the gate of the PMOSFET device, a gate applied with a bias voltage and a source connected to a bitline read path. The circuit is tuned to threshold voltages of the PMOSFET device and the NMOSFET device for sensing the threshold voltage of a NVM cell. By sensing threshold voltage states of the NVM cell, a bit information stored in the NVM cell can be fast determined.

### CROSS-REFERENCE TO RELATED APPLICATIONS

This application claims priority of No. 202411602816.1 filed in China on Nov. 8, 2024 under 35 USC 119, the entire contents of which are hereby incorporated by reference.

### BACKGROUND OF THE INVENTION

### Field of the Invention

The invention relates to integrated circuits for reading out the stored information in semiconductor non-volatile memory devices. In particular, multiple threshold voltages of Metal Oxide Semiconductor Field Effect Transistor (MOSFET) devices in the low power sensing amplify circuits are applied to fast determine the threshold voltages of semiconductor Non-Volatile Memory (NVM) cell devices for the stored bit information.

### Description of the Related Art

Semiconductor Non-Volatile Memory (NVM), and particularly Electrically Erasable Programmable Read-Only Memories (EEPROM), exhibit wide spread applicability in a range of electronic equipment from computers, to telecommunication hardware, and to consumer appliances. In general, EEPROM serves a niche in the NVM space as a mechanism for storing firmware and data that can be kept even with power off and can be altered as needed.

Data is stored in an EEPROM device by modulating its threshold

voltage (device on/off voltage) of the MOSFET device through the injection of charge carriers into the charge-storage layer from the substrate of the MOSFET device. For example, with respect to an N-channel MOSFET device, an accumulation of electrons in the floating gate, or in a dielectric layer, or in nano-crystal particles above the FET (Field Effect Transistor) channel region, causes the MOSFET device to exhibit a relatively high threshold voltage state.

The digital information stored in semiconductor NVM devices is represented by the threshold voltage states of the semiconductor NVM devices. For example, for the one bit storage in a single semiconductor NVM cell device the digital symbol “0” and “1” are represented by the high threshold voltage state and the low threshold voltage state for the semiconductor NVM devices, respectively. To read out the digital information stored in semiconductor NVM devices, the sensing circuits are designed to sense the threshold voltage states of the semiconductor NVM devices. In the conventional current sensing scheme as shown in FIG. 1 (prior art), the responding current Iᵣₛ for the semiconductor NVM device 140 accordingly with an applied gate voltage Vg generated by the current source 111 is compared with a referencing current I_{ref}. The current-voltage differential amplifier comparator 110 converts the responding current Iᵣₛ larger than the reference current I_{ref} for the low threshold voltage state to output the logic high voltage signal (V_{DD}) at output node out for digital symbol “1” and the responding current Iᵣₛ less than the reference current I_{ref} for the high threshold voltage state to output the logic ground voltage signal V_{SS} at output node out for digital symbol “0”, respectively. In this readout process, the large steady DC currents are mainly generated from the memory cells 140 (Iᵣₛ), the current amplifier 120 (Iₐₘ), the current-voltage differential amplifier comparator 110 (I_{dif}), and a referencing current generating circuit 130 (I_{ref}). Those large steady DC currents lead to high power consumption for reading out the bit information in semiconductor NVM cell devices.

In order to eliminate the large steady DC currents in the NVM readout process for both the time of sensing and standby, the readout circuits and their operating methods are previously disclosed in U.S. Pat. No. 7,995,398. In the readout circuit 200 shown in FIG. 2 (prior art), the voltage at the node 201 of a half latch connected to a selected semiconductor NVM device 202 through a conducting bitline path (comprising a bitline and multiplexer selection transistors) decreases from an initial pre-charging voltage (VR) by the discharging process of turning on the semiconductor NVM device 202 with the low threshold voltage toward the ground potential. While the voltage at the node 201 remains close to the initial pre-charging voltage (VR) without discharging process for the “off” semiconductor NVM device with the high threshold voltage during the sensing time period. The decreasing voltage at the node 201 for the discharging process of the “on” semiconductor NVM device with the low threshold voltage would reach a voltage flipping level such that the half latch begins to flip. The read voltage signals, V_{R} and the ground voltage, at the two output nodes 206 and 201 of the half latch are then fed to the inputs of the level-shifter latch to output the digital voltage signals, V_{DD} and the ground voltage (V_{SS}), at the complementary nodes 203 D and 204 D̅, respectively. In the circuit, the capability of the half latch to flip depends on the threshold voltages and current strengths of the P/N MOSFET devices, the applied read voltage V_{R} to the half latch, and the driving current strengths of the “low threshold voltage” NVM devices 202. Because of the positive feedback inherited in the half latch, the driving current strengths of the semiconductor NVM devices with the low threshold voltages are always competing with the MOSFET device current strength in the sensing circuit to flip. For example, in a failure flipping case, the driving current of the “on” semiconductor NVM device is too small to compete with the PMOSFET (MP₂) current, resulting in the voltage potential at the node 201 clamped to a voltage above the latch flipping voltage point. In such a failure scenario, the sensing circuit is flown with large currents through the series-connected P/N MOSFET paths in the latch to consume a large power.

To resolve the failure scenario for the previous low power readout circuit 200 in FIG. 2, the MOSFET threshold voltage sensing circuit in FIG. 3 (prior art) is previously disclosed in U.S. Pat. No. 10,147,492 (the disclosure of which is incorporated herein by reference in its entirety). The semiconductor NVM sensing circuit 300 includes a threshold voltage sensing circuit 310 (MP₁ and MN₁), a half latch 320, a voltage level-shifter latch 330, and a ground reset device MN₂. In the threshold voltage sensing circuit 310, the gate electrode 301 of the PMOSFET MP₁ attached with the pre-charging device MN₁ is connected to the bitline attached with a selected NVM device 340 through a bitline multiplexer selection MOSFET device unit 360, where Bₛₑₗ stands for “bitline selection” signal in FIG. 3. The source and drain electrodes of MP₁ are respectively connected to the node 304 biased with the read voltage V_{R} and to the node 302 of the half latch 320. The half latch 320 comprises a PMOSFET device MP₂ and an inverter formed by devices MP₃ and MN₃. The gates of devices MP₂ and MP₃ are cross-connected to the nodes 302 and 303 to form the half latch 320. The high voltage supply node of the half latch 320 is connected to the read voltage bias (V_{R}). The gate of the ground reset device MN₂ with its source and drain respectively tied to the ground and the node 302 receives the digital voltage signals from the node S̅e̅n̅s̅i̅n̅g̅ E̅n̅a̅b̅l̅e̅. The inputs nodes 305 and 306 (the gates of devices MN₄ and MN₅) of the voltage level-shifter latch 330 are respectively connected to the output nodes 303 and 302 of the half latch 320. The gates of the two PMOSFET devices MP₄ and MP₅ are cross-connected to the output nodes 307 and 308 for forming the voltage level-shifter latch 330.

In the read out mode, the pre-charging circuit 350 is activated for a period of charging time T_{chg} to charge the conducting bitline path (a selected bitline attached with the selected NVM device 340) to a voltage close to the read voltage V_{R}. When the node “Complementary Sensing Enable” S̅e̅n̅s̅i̅n̅g̅ E̅n̅a̅b̅l̅e̅ is applied with the digital low voltage signals (V_{SS}), the gate-charging device MN₁ and the reset device MN₂ are then turned off. The conducting bitline path is then connected to the gate of MP₁ device through the bitline multiplexer selection MOSFET devices (by activating one of the signals Bₛₑₗ) in unit 360. After turning off the pre-charging circuit 350, the selected wordline is applied with a wordline gate voltage V_{WR} to the gates of the selected NVM devices to discharge the connecting bitline to the ground voltage potential through the selected NVM devices 340. During the bitline discharging process, the voltage potentials at the gate 301 of MP₁ for the selected NVM devices 340 with the “low threshold voltage” less than the applied wordline gate voltage V_{WR} decrease much faster than those for the selected NVM devices 340 with the “high threshold voltage” larger than the applied wordline gate voltage V_{WR}. For those selected NVM devices 340 in the “low threshold voltage” state, the voltage potentials at the gates 301 of MP₁ are the first to reach the MP₁'s “on” voltage of (V_{R}−Vₜₕₚ), where Vₜₕₚ is the threshold voltage of MP₁. The MP₁ then flows strong enough “on” current to flip the half latch 320 with the assistance of the positive feedback device MP₂ to accelerate the half latch flipping process. The voltage signals at the output nodes 302 and 303 are fed into the input nodes of the voltage level-shifter latch 330 to flip the output nodes Q and Q̅ of the voltage level-shifter latch 330. The digital voltage signal at the output nodes Q of the semiconductor NVM sensing circuit 300 is then flipped to the high voltage signal (V_{DD}) for digital symbol “1”. Meanwhile since the voltage potentials at the gates 301 of MP₁ hardly reach the threshold voltage of MP₁ to turn on during the period of sensing time for the selected NVM devices in the “high threshold voltage” state, the digital voltage signal at the output node Q of the NVM sensing circuit 300 remains at its default voltage signal V_{SS} for digital symbol “0”.

After the sensing period, the node S̅e̅n̅s̅i̅n̅g̅ E̅n̅a̅b̅l̅e̅ is applied with the digital high voltage signals (V_{DD}) to turn on the pre-charging device MN₁ and the reset device MN₂ for recovering the voltage potential at node 301 to the read voltage V_{R} and the voltage potential at node 302 to the ground voltage V_{SS}, respectively. The time for discharging the bitline from the read voltage V_{R} to be below the threshold voltage Vₜₕₚ of MP₁ during the sensing period, and the time for charging the bitline from a dropped voltage back to the read voltage V_{R} by the pre-charging circuit 350 during the recovering period are the two dominant factors to limit the circuit sensing speed. Generally, it takes much longer time to discharge and charge the large total capacitance of a small MP₁ gate capacitance (approximately<fF(10⁻¹⁵ Farad)) and a large bitline capacitance (>several hundred fF) for a voltage potential difference (>Vₜₕₚ) through NVM cell currents and the pre-charging circuit 350. To improve the sensing time for the “on” state of the semiconductor NVM devices and to reduce the charging time for the large total capacitance loading, we apply a clamping NMOSFET device (MN_{c} 416 in FIG. 4) to separate the sensing node 411 from the read node 412 in the sensing circuit 400 to enlarge the voltage potential variations from V_{DD} at the sensing node 411 equivalent to the MP₁ gate node with a small gate capacitance for small voltage potential variations from the read voltage V_{R} at the read node 412 with a relatively large bitline capacitance.

In particular, the sensing circuit 400 in FIG. 4 is tuning at the threshold voltage of the sensing PMOSFET device (MP₁ 414) and the threshold voltage of the clamping NMOSFET device (MN_{c} 416). The extremely high circuit sensitivity can be achieved.

In one aspect of this invention is that since the typical switching characteristics of MOSFET devices including the semiconductor NVM devices are several orders of magnitude of responding current variations with a slope from approximately 60 millivolts to hundreds of millivolts per decade current in the MOSFET sub-threshold regions before reaching their threshold voltage points, the present sensing circuit 400 is extremely sensitive to the threshold voltage points of semiconductor NVM cell devices upon turning on. A 10-millivolt of NVM threshold voltage resolution shown in FIG. 8 has been obtained by the sensing circuit of this invention in one of the embodiments.

In one aspect of this invention is that since the present sensing circuit 400 is tuned at the threshold voltage point of a PMOSFET device 414 and the threshold voltage point of a clamping NMOSFET device (MN_{c} 416) in the circuit, the response time (i.e., from applying the gate voltage V_{WR} to the wordline to outputting the stored bit information at the node 431) of the circuit output at the threshold voltage points of the semiconductor NVM cell devices is in the range of several nanoseconds (10⁻⁹ seconds). The fast data accessing time for the stored bit information in semiconductor NVM by the sensing circuit 400 is comparable with those for DRAM (Dynamic Random Access Memory) and SRAM (Static Random Access Memory). The fast data accessing time for the semiconductor NVM can facilitate the fast code execution directly from the program code storage memory (semiconductor NVM) for saving some hierarchical levels of other fast random-access buffer memory provided by DRAM or SRAM for computing code execution.

In one aspect of this invention, the clamping NMOSFET device (MN_{c} 416) is turned on/off respectively for the voltage potentials (V_{R}) at the read node 412 less/greater than the clamping voltage V_{c}=(V_{b}−Vₜₕₙ), where V_{b} and Vₜₕₙ are the applied voltage bias to the gate and the threshold voltage of the clamping NMOSFET device (MN_{c} 416), respectively. Whereas the bias voltage V_{b} less than V_{DD} can be designed and generated by a voltage reference circuit from the high voltage supply V_{DD} in the memory chip, and the threshold voltage Vₜₕₙ of the clamping NMOSFET device (MN_{c} 416) is provided by the fabrication process.

In one aspect of this invention is that since the threshold voltages of MOSFET devices are given after the fabrication process, the present sensing circuit is insensitive to the chip external voltage supply variations.

In one aspect of this invention is that the present sensing circuit is non-differential type. The offset caused by the device mismatch in the sense amplifier circuit becomes irrelevant.

### SUMMARY OF THE INVENTION

FIG. 4 shows a schematic diagram of the sensing circuit 400 of the invention comprising a sense amplifier unit 410, a half latch 420 and a flip-flop buffer 430. The sense amplifier unit 410 is used to amplify the NVM bitline analog signals. The sense amplifier unit 410 includes a charging PMOSFET (PFET) device (MP_{chg} 417) to charge the sensing node 411 along with the read path 460 to an initial voltage potential (V_{DD}) and a clamping NMOSFET (NFET) (MN_{c} 416) having a clamping voltage potential V_{c}=(V_{b} Vₜₕₙ) at the read node 412. The sense amplifier unit 410 further includes a gate sensing PMOSFET device MP₁ 414 and a ground reset NMOSFET device (MN₃ 415). The half latch 420 is utilized to catch and convert the sensed voltage signals at node 421 from the output node 413 of the sense amplifier unit 410 into a stable latched digital voltage signal (V_{DD} or V_{SS}) at the node 422. The flip-flop buffer 430 stores the digital voltage signals from the digital signal output node 422 of the half latch 420 to output the digital voltage signal (V_{SS} or V_{DD}) of the stored bit information (“0” or “1) at the output node Q 431, i. e. “0” and “1” for the high/low threshold voltage states of the semiconductor NVM devices, respectively. Note that all the circuit units 410, 420, and 430 in the sensing circuit 400 are biased to the common digital high voltage potential (V_{DD}). In an alternative embodiment, the flip-flop buffer 430 stores the digital voltage signals from the node 421 of the half latch 420 to output the complementary digital voltage signal (V_{DD} or V_{SS}) of the stored bit information (“1” or “0”) at the complementary output node Q̅ 432.

The read path 460 starts from the gate-connected voltage sensing node 411 (connected to the gate of the sensing PMOSFET device MP₁ 414) to the drain electrode of the clamping NMOSFET device MN_{c} 416 with its source electrode as the read node 412 connected to an unit of multiplexer bitline switches (such as the n×1 multiplexer switches 610 (i) in FIG. 6) with an equivalent on-switch resistance R_{bsw} to a small metal bitline resistance Rb and a large bitline capacitance C_{b} (>several hundreds of fF). The small metal bitline resistance Rb is attached with a selected semiconductor NVM device 462 through the common source line to the ground potential. The bitline charging circuit 450 with the voltage charging output node 461 connected to the read node 412 is activated by the charging enable signal ChgEnb in the high voltage state (V_{DD}) at node 406 for charging the bitline to a read voltage V_{R}. After a period of charging time, the read voltage V_{R} reaches to a voltage potential greater than or equal to the clamping voltage V_{c}=(V_{b}−Vₜₕₙ), and the clamping NMOSFET device MN_{c} 416 is then turned off to prevent discharging the voltage potential from V_{DD} at the sensing node 411, wherein Vₜₕₙ is the threshold voltage of the clamping NMOSFET device (MN_{c} 416). Otherwise, if the charging read voltage V_{R} cannot reach the clamping voltage V_{c}=(V_{b}−Vₜₕₙ), the clamping NMOSFET device MN_{c} 416 is always on to flow the “on” current from the sensing node 411 to the read node 412, resulting in the voltage potential at the sensing node 411 dropping as for the “on” semiconductor NVM device 462. Thus, the PMOSFET device MP₁ is turned on and the node 413 has the supply voltage (V_{DD}).

FIG. 5 shows the read timing waveform for the sensing circuit 400 in FIG. 4. As the read clock signals shown in the first row of FIG. 5, the bitline charging circuit 450 is activated with the voltage signal ChgEnb in the high voltage level (V_{DD}) as shown in the third row upon receiving the rising edge of the read clock signal to charge the bitline for a period of time “T_{chg}” such that the voltage potential voltage at read node 412 as shown in the fifth row has reached a maximum read voltage potential V_{Rmax} greater than or equal to the clamping voltage potential V_{c}=(V_{b}−Vₜₕₙ). In the bitline charging period, since the SnEnb signal is de-activated with the ground voltage, the NMOSFET device MN₃ 415 and the PMOSFET device MP_{chg} 417 are turned on so that the node 413 is grounded and the sensing node 411 is charged to V_{DD}. After the bitline charging period, with the charging circuit 450 is de-activated (i.e., by the ChgEnb signal at ground voltage) in the data latching period T_{lch}, the sensing circuit 400 is activated with the sensing enable signal SnEnb in the high voltage (V_{DD}). In the sensing period, the charging PMOSFET device MP_{chg} 417 is turned off to stop charging the sensing node 411. For the semiconductor NVM devices with the low threshold voltage V_{thnvmL} less than the applied gate voltage (V_{WR}), the selected NMV device 462 is turned on to discharge the voltage potential at the read node 412 (solid curve 502 in FIG. 5) to the ground potential. As for the read path 460 discharging process for those “on” semiconductor NVM devices, the voltage potential at the read node 412 drops below the clamping voltage V_{c}=(V_{b}−Vₜₕₙ). The clamping NMOSFET device MN_{c} 416 is then turned on to conduct the read current Iₒₙ generated from the selected “on” semiconductor NVM device 462 for discharging the voltage potential at the sensing node 411 as the solid curve 512 shown in FIG. 5. When the voltage potential V₁ at the sensing node 411 drops below the threshold voltage Vₜₕₚ of the sensing PMOSFET device MP₁ 414 (i.e., V₁<(V_{DD}−Vₜₕₚ)), the half latch 420 starts to flip the voltage signal from V_{DD} to V_{SS} at its output node 422 with positive feedback to accelerate the latching process. The voltage signal at the node 422 from the half latch 420 is then stored in the flip-flop buffer 430 for the output Q (i.e., voltage signal V_{DD}) at node 431, as the solid curve 522 shown in FIG. 5 for the stored bit information of datum “1”. The stored bit information is associated with a “high” electrical conductance state of the selected NVM cell. While for those semiconductor NVM devices with a high threshold voltage V_{thnvmH} greater than the applied gate voltage (V_{WR}), the selected semiconductor NMV device 462 is turned off to disconnect from the ground potential. The voltage potential at the read node 412 remains unchanged as for the dotted curve 501 shown in FIG. 5. Meanwhile since the initial maximum read voltage potential V_{Rmax} at the read node 412 after charging from the bitline charging circuit 450 is greater than or equal to the clamping voltage V_{c}=(V_{b}−Vₜₕₙ), the clamping NMOSFET device MN_{c} 416 is off to prevent discharging the voltage potential from V_{DD} at the sensing node 411, as the dotted curve 511 shown in FIG. 5. The voltage signal at the half latch output node 422 remains V_{DD}. The voltage signal V_{DD} at the node 422 from the half latch 420 is then stored in the flip-flop buffer 430 for the output Q (i.e., voltage signal V_{SS}) at node 431 as the dotted curve 521 shown in FIG. 5 for the stored bit information of datum “0”. The stored bit information is associated with a “low” electrical conductance state of the selected NVM cell.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 shows the schematic depiction of the conventional sensing circuit for reading out the bit information stored in semiconductor NVM cell devices.

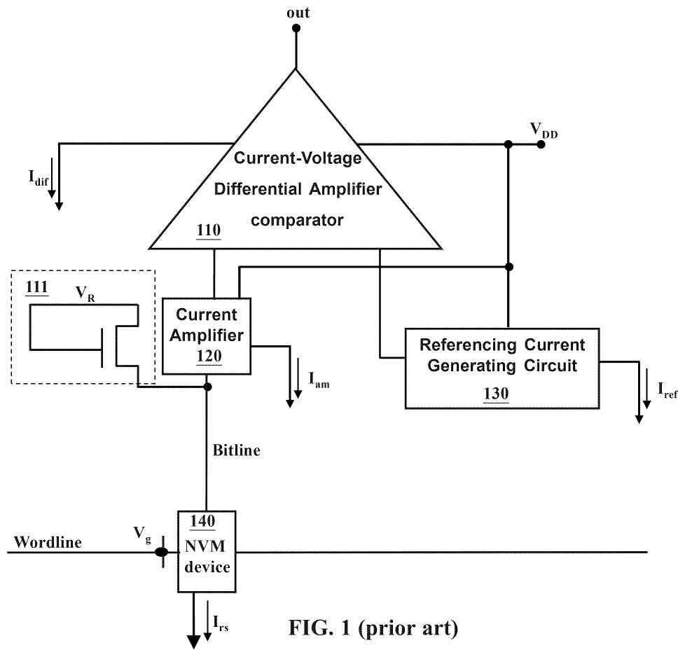

FIG. 2 shows a schematic diagram of a conventional sensing circuit to eliminate the DC currents generated in the conventional sensing circuit in FIG. 1 for reading out the bit information stored in semiconductor NVM devices.

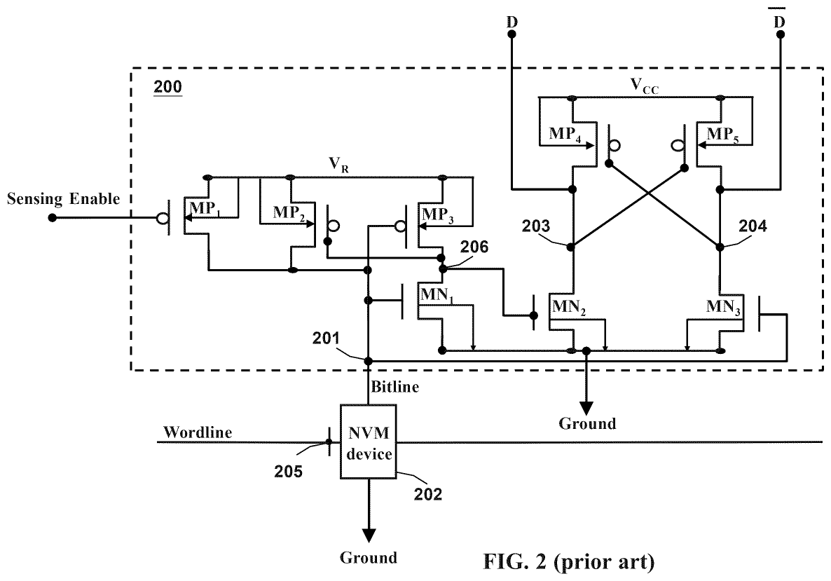

FIG. 3 shows a schematic diagram of a conventional sensing circuit to resolve the failure situation in the application of the sensing circuit shown in FIG. 2 due to the small driving currents of semiconductor NVM devices.

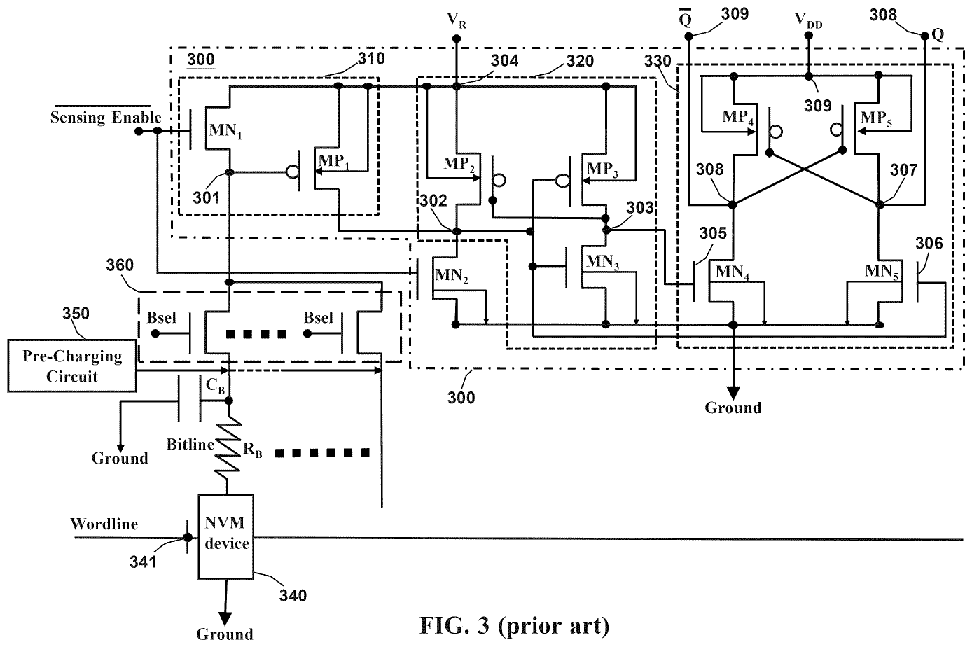

FIG. 4 shows the schematic diagram of the sensing circuit applying the principle of high sensitivity to the threshold voltage points of MOSFET devices and semiconductor NVM device for reading out the bit information stored in semiconductor NVM devices according to the present invention.

FIG. 5 shows the voltage signal timing waveform of the readout scheme with the sensing circuit depicted in FIG. 4 according to the present invention.

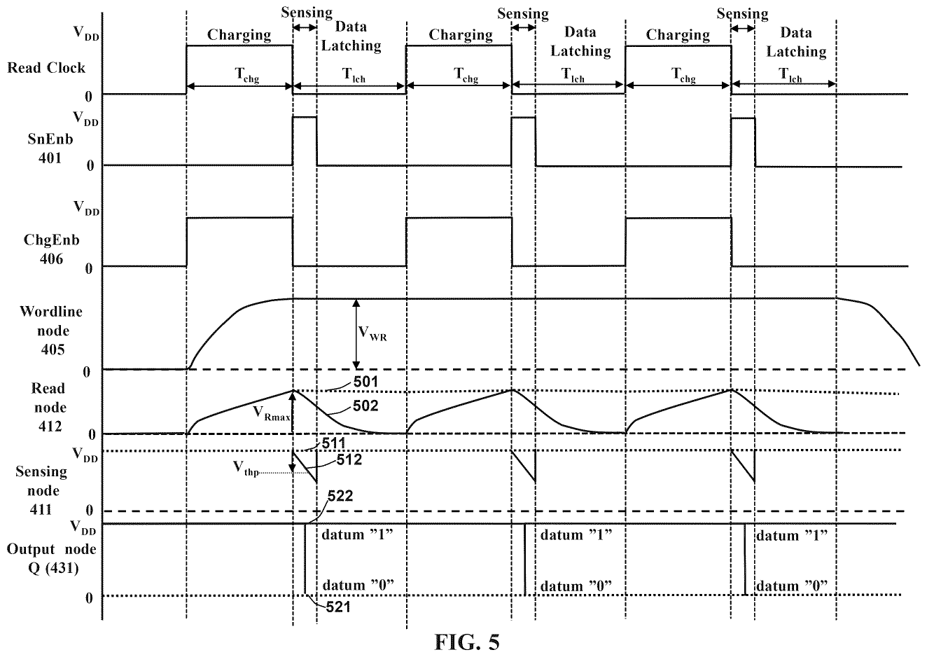

FIG. 6 is a schematic diagram for the sensing circuit 400 for a 64 Mb NOR flash memory array according to an embodiment of the present invention.

FIG. 7 shows a simulated voltage signal timing waveform of the sensing circuit 400 for the 64 Mb NOR flash memory in FIG. 6 according to the embodiment of the present invention.

FIG. 8 shows the cell threshold voltage distributions in a memory array obtained by applying the sensing circuit 400 according to an embodiment of the present invention.

### DETAILED DESCRIPTION OF THE PREFERRED EMBODIMENT

The present invention includes methods and schematics to fast read out the stored bit information from NVM cell devices in flash memory array. Those of ordinary skill in the art will immediately realize that the embodiment of the present invention described herein in the context of methods and schematics are illustrative only and are not intended to be in any way limiting. Other embodiment of the present invention will readily suggest themselves to such skilled persons having the benefits of this disclosure.

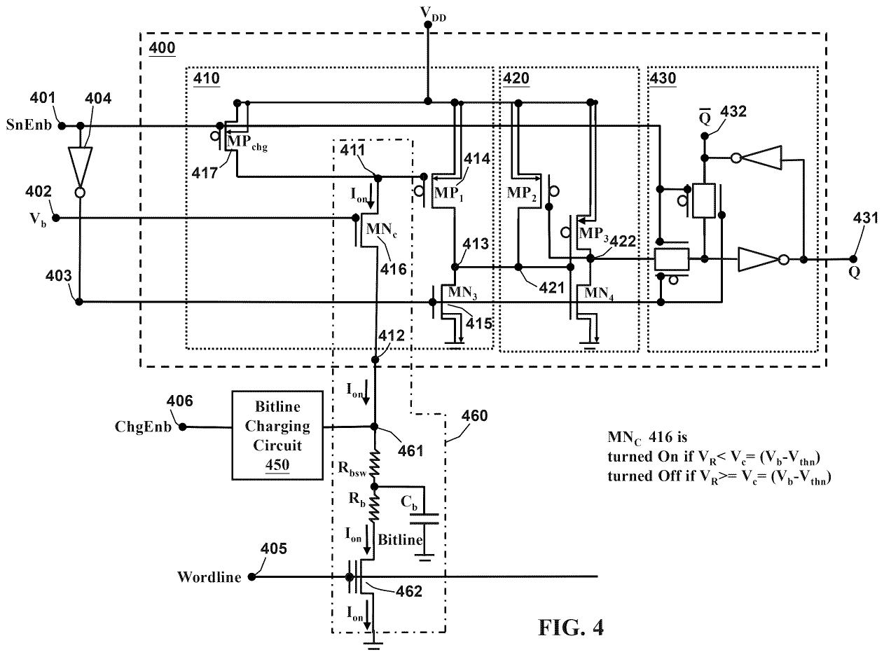

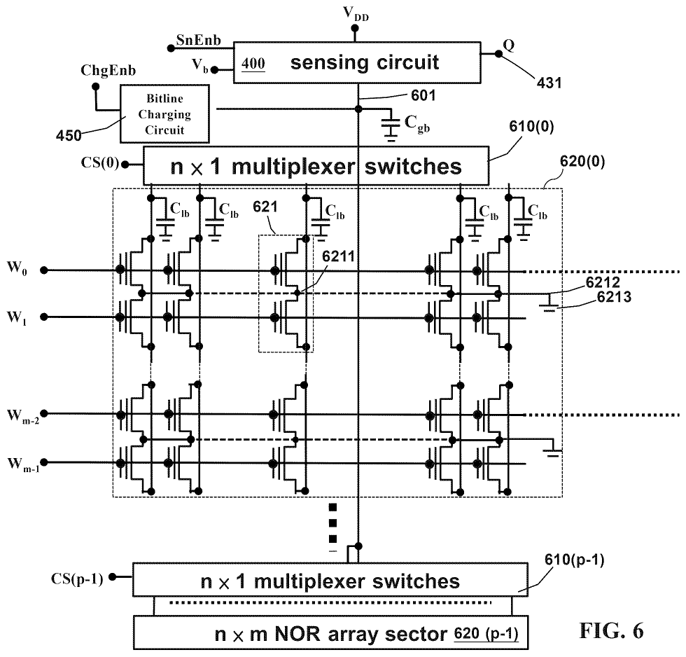

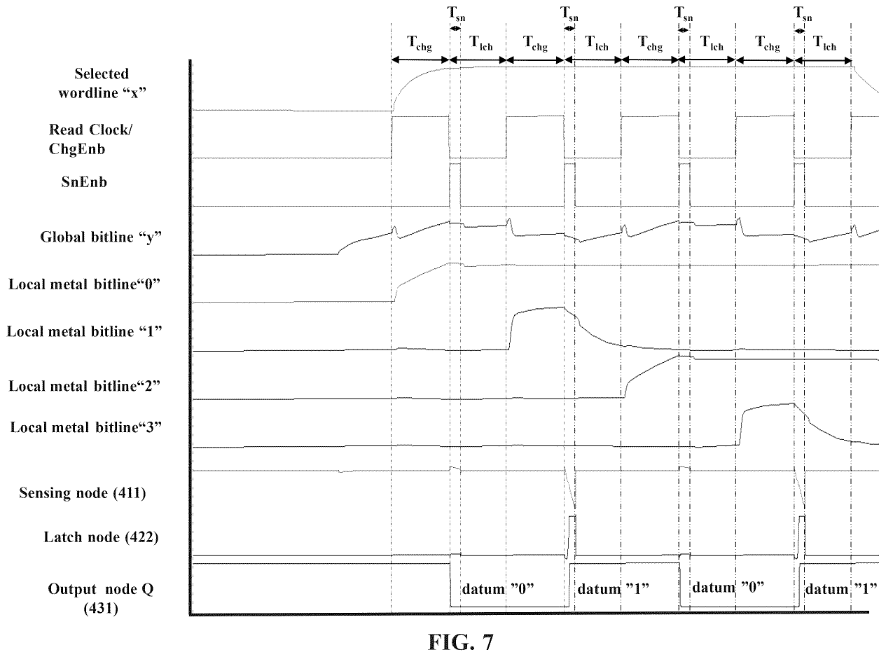

The sensing scheme of this invention for a NOR flash memory array is shown in FIG. 6. The sensing circuit 400 in FIG. 4 is connected to a global bitline 601 with a capacitance loading C_{gb} attached with p number of “n×m” NOR flash memory array sectors 620(i) and p number of “n×1” multiplexer switches 610(i) for i=0, 1, . . . , (p−1). The “n×1” multiplexer switch 610(i) is used to connect the global bitline 601 to one of n local metal bitlines according to the control signal CS(i). The sensing circuit 400 is designed to sense “p” sectors multiplied by (n×m) cells per sector devices in the NOR flash array. The “n×m” flash memory sector 620(i) is configured with “m” wordlines W₀˜Wₘ₋₁(control gates of NVM cell devices) and “n” local metal bitlines, each local metal bitline with a local capacitance loading C_{lb}. Each NOR flash pair devices 621 comprises two NVM cell devices with a common source electrode 6211. A row of common source electrodes 6211 are linked together to form a horizontal common source line 6212 connected to the ground potential 6213. In one embodiment of the 64 Mb NOR flash memory array, we have the wordline capacitance loading approximately 1.5 pF (10⁻¹² Farad), global bitline capacitance loading approximately 800 fF, and local metal bitline capacitance loading approximately 150 fF. The clamping bias voltage (V_{c}) is designed to be 1.1 V with the threshold voltage of clamping NMOSFET device MN_{c} 416 equal to approximately 0.7 V. FIG. 7 shows the simulated voltage signal timing waveform at the selected wordline node “x”, Charging Enable (ChgEnb) node, Sensing Enable (SnEnb) node, global bitline node “y”, and the four local metal bitline nodes “0”, “1”, “2”, and “3” for reading out the bit information at the sensing circuit output node Q for the four selected NVM cell devices with ‘high’ threshold voltage (datum “0”), ‘low’ threshold voltage (datum “1”), ‘high’ threshold voltage (datum “0”), and ‘low’ threshold voltage (datum “1”) attached to the local metal bitlines “0”, “1”, “2” and “3”, respectively. The charging time T_{chg} and the sensing time Tₛₙ are 35 ns and 5 ns with the applied wordline gate voltage (V_{WR}=3.7V), respectively.

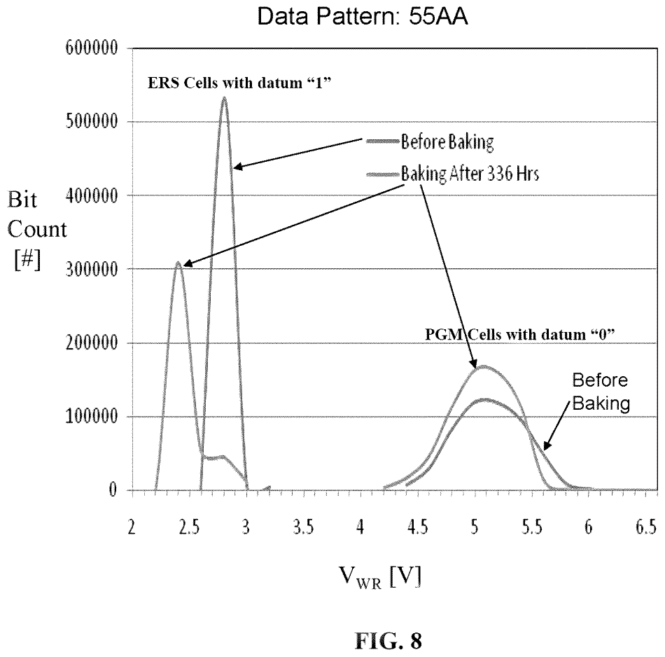

FIG. 8 shows the programmed/erased cell NVM (PGM/ERS cell NVM) threshold voltage distribution for a 1 Mb NOR flash array applying with the present sensing scheme and the sensing circuit 400 in FIG. 4 according to one embodiment of this invention. The cell memory array is pre-programmed with the data pattern 55 AAh, i.e., (0101 0101 1010 1010)b for every sixteen cell devices in the memory array. Note that the reading Q data “0” (output voltage signal (V_{SS})) from the sensing circuit 400 for the semiconductor NVM cell devices indicates the cell devices having “high” or programmed threshold voltages, and the reading Q data “1” (output voltage signal (V_{DD})) from the sensing circuit 400 for the semiconductor NVM cell devices indicates the cell devices having “low” or erased threshold voltages. Therefore, after programming data pattern 55 AAh to the entire memory array, half of cell devices in the memory array are the programmed cell devices with high threshold voltages, while the other half of cell devices in the memory array are the erase cell devices with low threshold voltages. The threshold voltages of semiconductor NVM cell devices in the memory array are scanned with the wordline gate voltage (V_{WR}) from 2 V to 6.5 V with a voltage step of 10 mV (DV=10 mV) by the sensing scheme and the sensing circuit 400 in FIG. 4. During the wordline voltage scan process, the sensing circuit outputs a voltage signal (V_{DD}) (“1”) at the Q node 431 if the applied wordline gate voltage (V_{WR}) is greater than the cell threshold voltage. The cell threshold voltage distribution for the applied wordline gate voltage V_{WR} is then obtained by the equation: the number of cells (V_{WR}) reading the output voltage (V_{DD})—the number of cells (V_{WR}+DV) reading the output voltage (V_{DD}), where ΔV is the wordline voltage increment=10 mV. FIG. 8 shows the original cell threshold voltage distribution for the programmed cells and the erased cells at room temperature and the cell threshold voltage distribution after 336 hours at temperature 250° C. baking for the programmed cells and the erased cells in the data retention experiment in one embodiment.

The aforementioned description of the preferred embodiment of the invention has been presented for purposes of illustration and description. It is not intended to be exhaustive or to limit the invention to the precise form or to exemplary embodiment disclosed. Accordingly, the description should be regarded as illustrative rather than restrictive. Obviously, many modifications and variations for the types of non-volatile memory devices including the conventional MOSFET devices with floating gate, charge trap dielectrics, or nano-crystals, and various array configurations of semiconductor NVM memories such as NOR-type flash, NAND type flash and EEPROM, will be apparent to practitioners skilled in this art. The embodiment is chosen and described in order to best explain the principles of the invention and its best mode practical application, thereby to enable persons skilled in the art to understand the invention for various embodiment and with various modifications as are suited to the particular use or implementation contemplated. It is intended that the scope of the invention be defined by the claims appended hereto and their equivalents in which all terms are meant in their broadest reasonable sense unless otherwise indicated. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiment of the invention. It should be appreciated that variations may be made in the embodiment described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A sensing circuit for sensing a stored bit from a selected Non-Volatile Memory (NVM) cell in a semiconductor NVM device, comprising:
a half latch coupled between a digital voltage rail having a supply voltage and a ground voltage node and having a voltage signal input node and a digital voltage signal output node;
a PMOSFET device having a source electrode connected to the digital voltage rail and a drain electrode connected to the voltage signal input node;
a switch device connected to the digital voltage rail for selectively charging a gate electrode of the PMOSFET device in response to a first control signal;
a NMOSFET device having a drain electrode connected to both the switch device and the gate electrode of the PMOSFET device, a gate electrode applied with a bias voltage V_{b} and a source electrode connected to a bitline read path coupled with the selected NVM cell; and
a reset transistor connected between the voltage signal input node and the ground voltage node for selectively connecting the voltage signal input node to the ground voltage node in response to a second control signal.

2. The circuit according to claim 1, further comprising:
a flip-flop buffer coupled to the digital voltage signal output node for storing a digital voltage signal at the digital voltage signal output node to output the stored bit according to the digital voltage signal at the digital voltage signal output node.

3. The circuit according to claim 1, wherein the stored bit is associated with an electrical conductance state of the selected NVM cell.

4. The circuit according to claim 1, wherein after the bitline read path is charged to an initial voltage unable to reach (V_{b}−Vₜₕₙ), the NMOSFET device and the PMOSFET device are turned on to cause the voltage signal input node to have the supply voltage.

5. The circuit according to claim 1, wherein after the bitline read path is charged to an initial voltage greater than or equal to (V_{b}−Vₜₕₙ) and a gate voltage is applied to a word line associated with the selected NVM cell, an electrical conductance state of the selected NVM cell determines whether the bitline read path discharges, where Vₜₕₙ denotes a threshold voltage of the NMOSFET device.

6. The circuit according to claim 5, wherein a voltage V_{R} at the bitline read path drops if the selected NVM cell is turned on with a high conductance state, otherwise V_{R} remains unchanged.

7. The circuit according to claim 5, wherein the NMOSFET device is turned on when a voltage V_{R} at the bitline read path drops below (V_{b}−Vₜₕₙ), otherwise the NMOSFET device is turned off with a low conductance state.

8. The circuit according to claim 7, wherein after the gate electrode of the PMOSFET device is charged to the supply voltage, the voltage signal input node is reset by the reset transistor and the NMOSFET device is turned on, when a voltage V₁ at the gate electrode of the PMOSFET device drops less than (V_{DD}−Vₜₕₚ), the PMOSFET device is turned on to cause the voltage signal input node to have the supply voltage, otherwise the PMOSFET device is turned off and the voltage signal input node remains at a ground voltage, where Vₜₕₚ denotes a threshold voltage of the PMOSFET device and V_{DD} denotes the supply voltage.

9. A method of sensing a stored bit from a selected non-volatile memory (NVM) cell in a semiconductor NVM device comprising a sensing circuit comprising a PMOSFET device, a NMOSFET device and a half latch having a voltage signal input node and a digital voltage signal output node, the half latch being coupled between a digital voltage rail having a supply voltage and a ground voltage node, wherein a drain electrode and a source electrode of the PMOSFET device are respectively connected to the voltage signal input node and the digital voltage rail, wherein a drain electrode and a gate electrode of the NMOSFET device are respectively connected to a gate electrode of the PMOSFET device and applied with a bias voltage V_{b}, the method comprising:
respectively charging a bitline read path and the gate electrode of the PMOSFET device to an initial voltage and the supply voltage;
resetting the voltage signal input node to a ground voltage;
stopping charging and resetting;
connecting the bitline read path to the selected NVM cell;
applying a gate voltage to a word line associated with the selected NVM cell;
selectively discharging by the bitline read path and the gate electrode of the PMOSFET device according to the initial voltage and electrical conductance states of the NMOSFET device and the selected NVM cell; and
obtaining a voltage at the voltage signal input node according to an electrical conductance state of the PMOSFET device.

10. The method according to claim 9, wherein the step of selectively
discharging comprises:
if the initial voltage is unable to reach (V_{b}−Vₜₕₙ), causing the NMOSFET device and the PMOSFET device to be turned on so that the voltage signal input node has the supply voltage, where Vₜₕₙ denotes a threshold voltage of the NMOSFET device.

11. The method according to claim 9, wherein the step of selectively discharging comprises:
if the initial voltage is greater than or equal to (V_{b}−Vₜₕₙ),
selectively discharging by the bitline read path according to the electrical conductance state of the selected NVM cell, and
selectively discharging by the gate electrode of the PMOSFET device according to the electrical conductance states of the NMOSFET device and the selected NVM cell.

12. The method according to claim 11, wherein the step of selectively discharging by the bitline read path comprises:
causing the bitline read path to discharge if the selected NVM cell is turned on, otherwise causing the bitline read path to maintain the initial voltage; and
when a voltage at the bitline read path drops below (V_{b}−Vₜₕₙ), causing the NMOSFET device to be turned on, otherwise causing the NMOSFET device to be turned off.

13. The method according to claim 12, wherein the step of selectively discharging by the gate electrode of the PMOSFET device comprises:
when the selected NVM cell and the NMOSFET device are turned on, causing the gate electrode of the PMOSFET device to discharge from the supply voltage; and
when a voltage at the gate electrode of the PMOSFET device drops below (V_{DD}−Vₜₕₚ), causing the PMOSFET device to be turned on so that the voltage signal input node has the supply voltage, otherwise the PMOSFET device is turned off and the voltage signal input node maintains the ground voltage, where Vₜₕₚ denotes a threshold voltage of the PMOSFET device and V_{DD} denotes the supply voltage.

14. The method according to claim 9, further comprising:
generating a digital voltage signal at the digital voltage signal output node by the half latch according to the voltage of the voltage signal input node; and
outputting the stored bit according to the digital voltage signal at the digital voltage signal output node.

15. The method according to claim 14, wherein a response time from the
step of applying the gate voltage to the step of outputting the stored bit is in the range of several nanoseconds 16. The method according to claim 9, wherein the stored bit is related to the electrical conductance state of the selected NVM cell.
